(19) United States
(12) Patent Application Publication
(10) Pub. No.: US 2009/0059604 A1
(43) Pub. Date: Mar. 5, 2009

(54) HEAT DISSIPATION DEVICE FOR LIGHT EMITTING DIODE MODULE

(75) Inventors: GUANG YU, Shenzhen (CN); CHENG-TIEN LAI, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/845,742

(22) Filed: Aug. 27, 2007

(51) Int. Cl. F21V 29/00; H05K 7/20

(52) U.S. Cl. 362/373; 361/709

(57) ABSTRACT

A heat dissipation device for a light emitting diode (LED) module includes a heat sink, a plurality of heat pipes received in the heat sink and a heat-absorbing plate thermally attached to the heat pipes and the LED module and located therebetween. The heat sink includes a base and a plurality of fins mounted on the base. The base defines a plurality of grooves for accommodating the heat pipes therein. Top surfaces of the heat pipes are coplanar with a top face of the base of the heat sink so that the heat-absorbing plate has an intimate contacting with the top face of the base of the heat sink and the top surfaces of the heat pipes, whereby the heat pipes can quickly transfer heat from the LED module to the heat sink via the heat-absorbing plate.

### BACKGROUND OF THE INVENTION

1. Field of the Invention

The present invention relates to a heat dissipation device, more particularly to a heat dissipation device for a light emitting diode module.

2. Description of Related Art

A light emitting diode (LED) is a device for transferring electricity to light by using a theory that, if a current is made to flow in a forward direction in a junction comprising two different semiconductors, electrons and holes are coupled at the junction to generate a light beam. The LED has an advantage that it is resistant to shock, and has an almost eternal lifetime under a specific condition; thus, more and more LED modules for different applications are being developed.

LED modules for use in a display or an illumination device require many LEDs, and most of the LEDs are driven at the same time, which results in a quick rise in temperature of the LED module. Since generally the LED modules do not have heat dissipation devices with good heat dissipating efficiencies, operation of the general LED modules has a problem of instability because of the rapid build up of heat. Consequently, the light from the LED module often flickers, which degrades the quality of the display or illumination.

What is needed, therefore, is a heat dissipation device for an LED module, which can overcome the above-described disadvantages.

### SUMMARY OF THE INVENTION

A heat dissipation device for a light emitting diode (LED) module is disclosed. The heat dissipation device comprises a heat sink, a plurality of heat pipes thermally attached to and received in the heat sink and a heat-absorbing plate thermally attached to the heat pipes and the LED module and located therebetween. The heat sink comprises a base and a plurality of fins mounted on the base. The base defines a plurality of grooves for accommodating the heat pipes therein. A top surface of each of the heat pipes is coplanar with a top face of the base of the heat sink so that the heat-absorbing plate has an intimate contacting with the top face of the base of the heat sink and the top surfaces of the heat pipes, whereby the heat pipes can quickly transfer heat from the LED module to the heat sink via the heat-absorbing plate.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of a heat dissipation device in accordance with a preferred embodiment of the present invention and an LED module;

FIG. 2 is a partially assembly view of FIG. 1;

FIG. 3 is an assembled view of FIG. 2; and

FIG. 4 is similar to FIG. 3, but viewed from a bottom aspect.

### DETAILED DESCRIPTION OF THE INVENTION

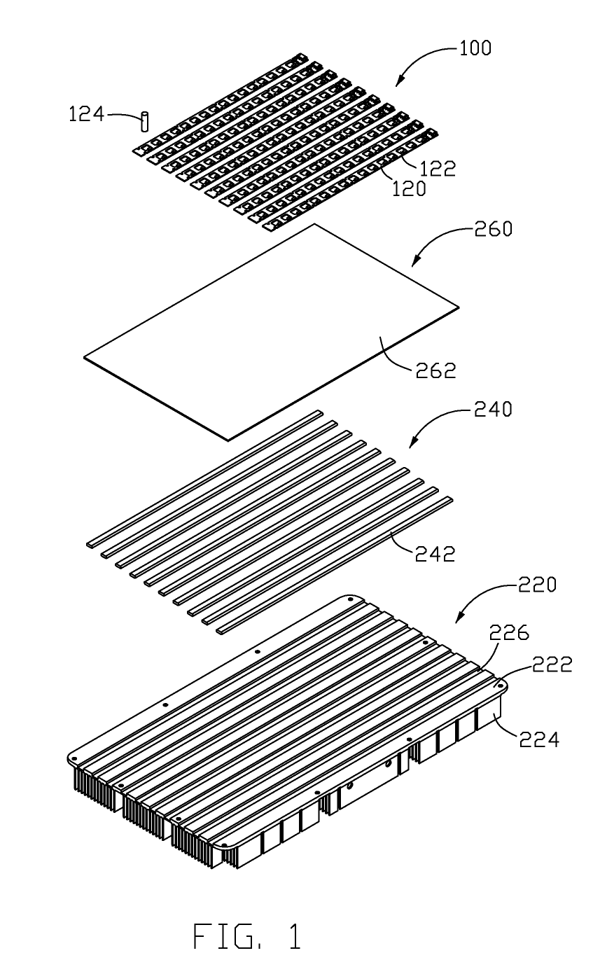

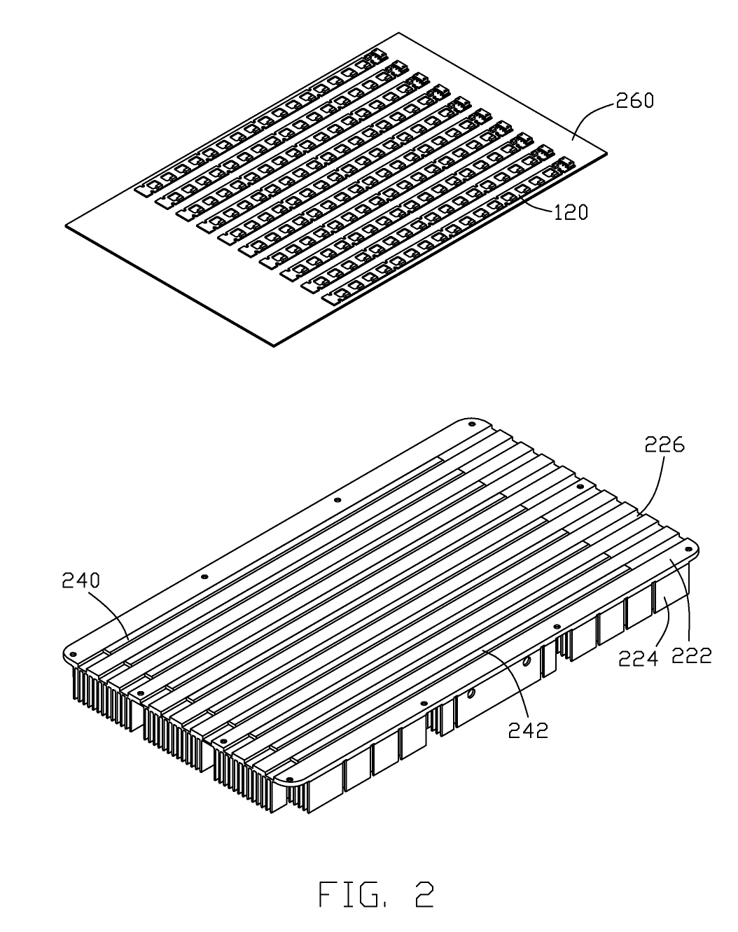

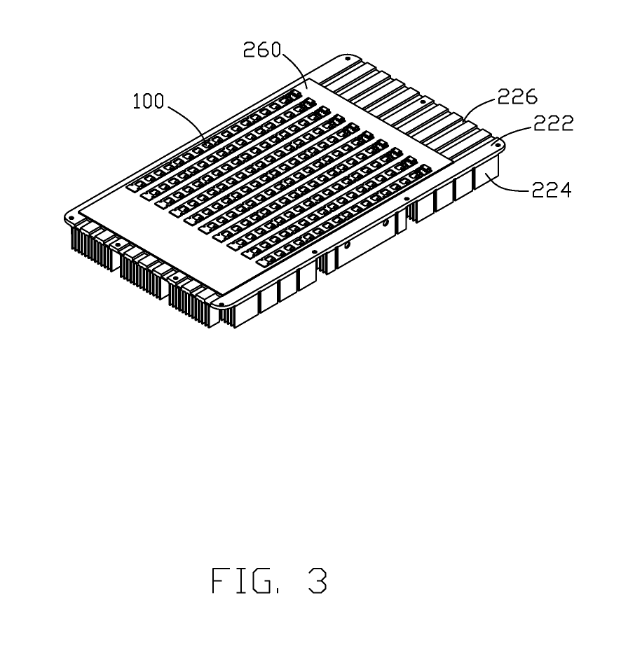

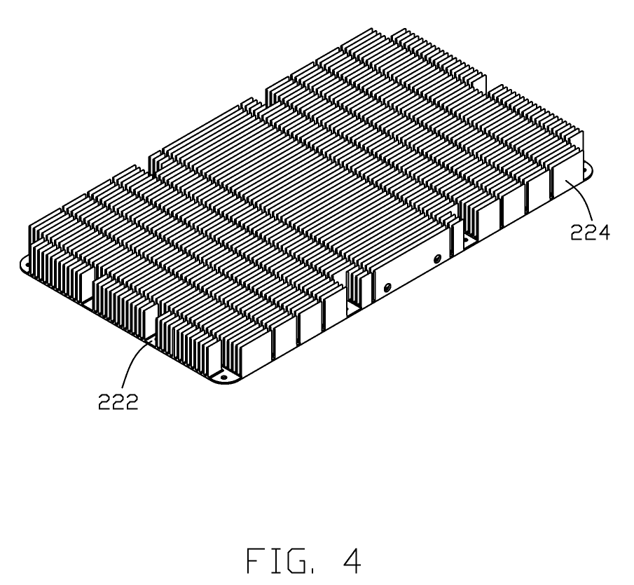

Referring to FIGS. 1-4, a heat dissipation device in accordance with a preferred embodiment of the present invention is illustrated. The heat dissipation device is used to cool down an LED module 100 to keep the LED module 100 working within an acceptable temperature range.

In this embodiment, the LED module 100 comprises several juxtaposed printed circuit boards 120. Each printed circuit board 120 has a plurality of through holes 122 defined therein. The through holes 122 are arrayed in rows and lines for receiving lower portions of LEDs 124 (only one shown) therein. Alternatively, these printed circuit boards 120 can be replaced by a larger single printed circuit board, which has a matrix of through holes defined therein. The LEDs 124 are used to be installed into the corresponding through holes 122 of the printed circuit boards 120, electrically bonded to the printed circuit boards 120, and electrically connected to circuits (not shown) provided on the printed circuit boards 120. Therefore, the LED module 100 is formed.

Before the LED module 100 is driven to generate light, the heat dissipation device is mounted on a bottom surface of the printed circuit boards 120.

The heat dissipation device comprises a heat sink 220, several heat pipes 240 thermally attached to the heat sink 220 and a heat-absorbing plate 260 thermally contacting with the heat pipes 240 and the LED module 100. The heat sink 220 comprises a base 222 and a plurality of fins 224 tightly mounted to a bottom surface (not shown) of the base 222. The fins 224 of the heat sink 220 are arranged in rows and lines. The base 222 is a substantially rectangular shape and has an area larger than that of the heat-absorbing plate 260. A plurality of grooves 226 are defined in a top face (not labeled) of the base 222 and arrayed in parallel lines, for accommodating the heat pipes 240 therein. The heat pipes 240 are all straight and flattened heat pipes. The heat pipes 240 are parallel to each other and separated from each other by a certain distance determined by the arrangement of the printed circuit boards 120. Each heat pipe 240 has a top flat surface 242 and a bottom flat surface (not shown) opposite to the top flat surface 242. In this embodiment, the heat-absorbing plate 260 is a substantially rectangular metal plate having good heat conductivity, and has a top face 262 for contacting the bottom surfaces of the printed circuit boards 120 and a bottom face (not shown) opposite to the top face 262 for contacting the top flat surfaces 242 of the heat pies 240 and the top face (not labeled) of the base 222 of the heat sink 220.

Additionally, the number of the heat pipes 240 may be increased or decreased to meet the increase or decrease of the number of the printed circuit boards 120 and the LEDs 124, which is made according to the required illumination of the LED module 100.

In assembly of the heat dissipation device, the heat pipes 240 are fixed in the grooves 226 of the base 222 of the heat sink 220 by soldering or adhesive. The top flat surfaces 242 of the heat pipes 240 are arranged coplanar with the top face of the base 222 of the heat sink 220. The heat-absorbing plate 260 is fixed on the top face of the base 222 of the heat sink 220 and the top flat surfaces 242 of the heat pipes 240 by soldering, with the bottom face of the heat-absorbing plate 260 intimately contacting with the top flat surfaces 242 of the heat pipes 240 and the top face of the base 222 of the heat sink 220 so that the heat pipes 240 can quickly transfer the heat of the LEDs 124 of the LED module 100 to the heat sink 220 via the heat-absorbing plate 260. The printed circuit boards 120 are bonded to the top face 262 of the heat-absorbing plate 260 with each printed circuit board 120 corresponding to a corresponding heat pipe 240, for facilitating transfer of the heat from the LEDs 124 to the heat pipes 240 via the heat-absorbing plate 260.

In use, the top surface 262 of the heat-absorbing plate 260 of the heat dissipation device thermally contacts the printed circuit boards 120 and absorbs the heat from the LEDs 124. The heat pipes 240 absorb the heat in the heat-absorbing plate 260 and directly transfer the heat to the fins 224 of the heat sink 220 to be dissipated to ambient air.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device for a light emitting diode (LED) module, the heat dissipation device comprising:
a heat sink comprising a base and a plurality of fins attached to the base, the base defining a plurality of grooves therein;
a plurality of flattened heat pipes received in the grooves of the base of the heat sink and top surfaces of the flattened heat pipes being coplanar with a top face of the base of the heat sink; and
a heat-absorbing plate comprising a first surface and a second surface opposite to the first surface, the first surface being attached to the top face of the base and the top surfaces of the heat pipes, the second surface being adapted for being attached to the LED module and absorbing heat from the LED module.

2. The heat dissipation device as claimed in claim 1, wherein the grooves of the base of the heat sink are arrayed in parallel lines.

3. The heat dissipation device as claimed in claim 1, wherein the fins of the heat sink are arranged in rows and lines.

4. An LED device, comprising:
a plurality of printed circuit boards each having a plurality of LEDs arrayed thereon; and
a heat dissipation device attached to the printed circuit boards for absorbing heat from the LEDs, the heat dissipation device comprising:
a heat sink comprising a base and a plurality of fins mounted on the base, the base defining a plurality of grooves therein;
a plurality of heat pipes received in the grooves of the base of the heat sink; and
a heat-absorbing plate comprising a first surface and a second surface opposite to the first surface, the first surface being attached to a top face of the base of the heat sink and top surfaces of the heat pipes, the second surface being attached to bottom surfaces of the printed circuit boards and absorbing the heat from the LEDs.

5. The LED device as claimed in claim 4, wherein each printed circuit board defines a plurality of through holes for receiving the LEDs therein, and the LEDs are electrically bonded to the printed circuit boards.

6. The LED device as claimed in claim 4, wherein the heat pipes are flattened and straight heat pipes, and wherein the top surfaces of the flattened pipes are coplanar with the top face of the base of the heat sink.

7. The LED device as claimed in claim 4, wherein the heat pipes are located parallel to each other.

8. The LED device as claimed in claim 4, wherein the grooves in the base of the heat sink are arrayed in parallel lines.

9. An LED device comprising:
a heat sink having a face defining a plurality of grooves therein;
a plurality of heat pipes received in the grooves, wherein each heat pipe has a flat surface coplanar with the face of the heat sink;
a heat absorbing plate having a first surface attached to and thermally connecting with the face of the base of the heat sink and the flat surfaces of the heat pipes; and
an LED module having at least a printed circuit board with a plurality of the LEDs mounted thereon, being attached to and thermally connecting with a second surface of the heat absorbing plate, the second surface being opposite to the first surface.

10. The LED device as claimed in claim 9, wherein the at least a printed circuit board defines a plurality of holes receiving the LEDs therein.

11. The LED device as claimed in claim 9, wherein the heat sink has a plurality of fins extending in a direction away from the heat pipes.
